(19) United States
(12) Patent Application Publication
(10) Pub. No.: US 2002/0009638 A1
(43) Pub. Date: Jan. 24, 2002

(54) Composite coated electrode and method of fabricating the same

(76) Inventors: Marion Dattilo, Rolla, MO (US); Leonard J. Lutz, Rolla, MO (US)

Correspondence Address: Michael R. Swartz, Esq., 205 Royal Oak Avenue, Pittsburgh, PA, 15235, US

(21) Appl. No.: 09/887,846

(22) Filed: Jun. 22, 2001

Related U.S. Application Data
(60) Provisional application No. 60/213,771, filed on Jun. 23, 2000.

(51) Int. Cl. H01M 4/16; H01M 4/22; C25C 1/16; C25C 1/08; C25C 1/12; C25C 7/02; C23C 14/08; C23C 14/34; B23H 7/24; B05D 5/12

(52) U.S. Cl. 429/215; 204/290.01; 204/290.11; 204/290.15; 429/217; 429/224; 427/126.3; 204/192.15; 204/164; 205/575; 205/594; 205/587; 205/603

(57) ABSTRACT

A coated composite electrode for supporting an anodic electrochemical reaction includes a substrate composed of an electrically conductive metal and a mixture composed of lead and manganese oxides of between about 70 and 90 weight percent and of binders and extenders together being of between about 10 and 30 weight percent. The mixture is in the form of a coating on the substrate which constitutes a site of electrochemical oxidation. The coating is pressed above about 1500 psi pressure and at a temperature within the range of about 25 to 230 degrees C. The composite electrode provides corrosion inhibition for the lead alloy and improved current efficiency in systems with iron, such as copper electrowinning.

This utility patent application claims the benefit of the provisional patent application No. 60/213,771 filed Jun. 23, 2000.

### BACKGROUND OF THE INVENTION

1. Field of the Invention

The present invention generally relates to an electrode applicable to various electrolytic processes or devices and, more particularly, is concerned with a composite coated electrode and a method of fabricating the electrode.

2. Description of the Prior Art

The electrowinning of metals from aqueous media relies on a stable anode to support the electrochemical oxidation of water to oxygen gas and the replenishment of acid. Anodes employed in metal electrowinning are lead alloys which form layers of lead oxidation products including lead dioxide. The lead dioxide is considered to be the component that allows lead to act as an anode in these situations since it is a semiconductor and the site of oxidation reactions such as water splitting.

Research in the electrowinning of lead from a variety of media, including fluorine acids, fluosilicic and fluoboric, demonstrated the aggressive attack of the medium upon the anode. As disclosed in U.S. Pat. No. 5,632,872 which issued to Dattilo in 1997, it was found that the use of mixed metal oxides, lead dioxide and manganese dioxide, provides an efficient anodic surface when compressed with binders. This observation was sufficient reason to test this concept in zinc and copper sulfate media. Zinc and copper are electrodeposited from sulfate media to produce these metals in commercial electrowinning. This was accomplished as predicted with a lowered cell voltage in some cases as in the lead electrowinning system. Also, it demonstrated the ability to form a lead dioxide based electrode that could be used as a positive plate in a lead acid battery.

In commercial metal electrowinning, such as is found in especially zinc and copper but also nickel, cobalt or any other acid soluble metal sulfate system, the presence of impurities and additives alters the electrochemical reactions which occur at the lead alloy anode. Although oxygen evolution is the major product at the anode, other species such as manganese and iron are involved in oxidation reactions at the anode surface. A list of many of the important reactions is as follows. This list is not all-inclusive but addresses the most important reactions for the following discussion and to demonstrate the influence of the composite electrode.

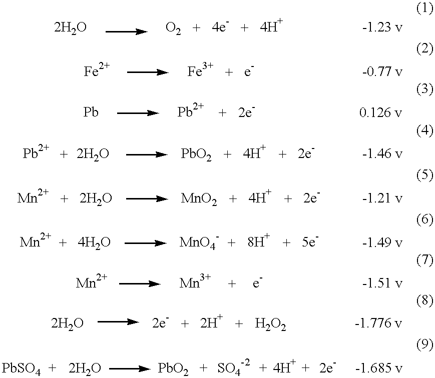

The anode provides a release of acid for the recycling of electrolyte and gas evolution provides hydrodynamic mixing in the cell. With the lead electrode, reaction (9) above occurs since a sulfate media is involved.

Cell performance, or current efficiency, is measured by Faraday's law such that the current density is a measure of the rate of reaction in these systems. The current efficiency is determined by this criteria and has been determined to be highly affected by the reaction of iron oxidation and to a lesser extent the manganese ion oxidation products. Manganese in the solution also reacts with the lead alloy anode's surface oxidation products that are predominantly lead oxides. Reactions (4) and (5) above contribute to the sludge products found in commercial cells due to lead alloy corrosion. The lead dioxide component of the surface is usually considered to be the site of water oxidation to oxygen. In all cases of industrial operations, a lead alloy anode is employed which is usually lead-0.75%silver for zinc electrowinning and lead-cadium-tin for copper electrowinning. These are the most widespread processes in commercialization.

The inventors herein have perceived that a need exists for improvement of the lead alloy anode so as to further inhibit corrosion, lower cell voltage and increase current efficiency.

### SUMMARY OF THE INVENTION

The present invention provides a composite coated electrode and a method of fabricating the same designed to satisfy the aforementioned need. A composite coating on a substrate of the electrode to provide a new site of electrochemical oxidation will serve to inhibit corrosion of the substrate. Also, the voltage of a cell employing the anodic electrode will be lowered and the current efficiency of the cell will be higher. Because of these improvements, the composite coated electrode of the present invention reduces the maintenance of the electrode and stabilizes cell performance.

Accordingly, the present invention is directed to a composite coated electrode, such as an anodic electrode, for supporting an electrochemical reaction. The electrode comprises: (a) a substrate composed of an electrically conductive metal; and (b) a mixture composed of lead and manganese oxides of between about 70 and 90 weight percent and of binders and extenders together being of between about 10 and 30 weight percent. The mixture is applied as a coating on the substrate to form a new site of electrochemical oxidation. The mixture is applied so as to form a coating on the substrate and then the coating is pressed above 1500 psi pressure and at temperatures of 25 to 230 degrees C. The electrically conductive metal preferably is a lead alloy. The binders preferably are polyvinylidene difluoride and/or derivatives or copolymers, silicates, minor metal oxides, fibers, and/or mixtures of same. The extenders preferably are carbon fibers, silicates, minor metal oxides, and metal silicates.

The present invention also is directed to a method of fabricating a composite coated electrode, such as an anodic electrode, which comprises the steps of: (a) providing a substrate composed of an electrically conductive metal, such as a lead alloy; (b) providing a mixture composed of lead and manganese oxides of between about 70 and 90 weight percent and of binders and extenders together being of between about 10 and 30 weight percent; and (c) applying the mixture to the substrate to form a coating thereon that constitutes a new site of electrochemical oxidation. The mixture is applied so as to form a coating on the substrate. As examples, to form the coating the mixture is applied as a dry powder, a slurry paste or a slurry spray, or by sputtering or electrostatic deposition. The mixture forming the coating is then pressed above 1500 psi pressure and at temperatures of 25 to 230 degrees C.

These and other features and advantages of the present invention will become apparent to those skilled in the art upon a reading of the following detailed description wherein there is shown and described an illustrative embodiment of the invention.

### DETAILED DESCRIPTION OF THE INVENTION

The present invention relates to a composite coated electrical electrode for supporting an electrochemical anodic reaction and the method of fabricating the electrode. The composite coated electrode is particularly suited for supporting an anodic reaction in aqueous electrolytic media during metal electrowinning, especially, in zinc and copper cathodic electrolytic production. However, it is to be understood, that the present invention is not only applicable to an anode used in an electrolytic cell, but also is applicable to a cathode used in an electrolytic cell if you change the oxide mixture with other materials, and further is applicable to a positive electrode used in a galvanic cell.

The composite coated electrode comprises a substrate composed of an electrically conductive metal and a composite mixture composed of lead and manganese oxides of between about 70 and 90 weight percent and of binders and extenders together being of between about 10 and 30 weight percent. The mixture is provided in the electrode in the form of a coating formed on the substrate which constitutes a new site of electrochemical oxidation. The coating is formed by being pressed above about 1500 psi pressure and at a temperature within the range of about 25 to 230 degrees C. The electrically conductive metal of the substrate is a lead alloy or other suitable metal depending upon the application.

Laboratory observations about the composite coated electrode of the present invention have been verified by actual testing in plant-like conditions. Testing with actual plant electrolytes from copper and zinc facilities has shown that the use of the composite coated electrode increases the cathode current efficiency and lowers the amount of anode sludge which is a lead material from anode corrosion. The mixed metal oxide matrix of lead and manganese dioxides of the coating provides a cell voltage lowering initially but the composite itself is an altering material. Electrochemical reactions that occur in the composite are different in rate than the reactions that occur in the lead dioxide layers on a normal lead alloy. The formation of different levels of lead sulfate and lead dioxide for the lead alloys versus the composite anode was evaluated by X-ray diffraction. The differences are impacted by the availability of the manganese impurity in the electrolyte.

Also, the testing of the composite coated electrode in actual plant electrolytes from copper and zinc facilities showed that the use of polyethylene as the binder was inferior to and thus was replaced by polyvinylidene difluoride (PVDF) or its copolymers in forming the improved composite coated electrode. Thus, although polyethylene in some instances can be used as the binder, PVDF or its copolymers is the preferred binder material. The addition of other matrix extender materials such as fibers and absorbants are incorporated in the mixture to stabilize the composite coating of the improved electrode.

In order to make the composite coated electrode of the present invention amendable to commercial application, in an exemplary embodiment the substrate to which the composite coating is applied is in the form of the lead alloy anode used heretofore in commercial practice. The lead alloy substrate is cleaned and the composite mixture is applied thereto as a slurry, spray or by any other suitable means to provide the coating of a uniform thickness on the substrate. After drying the water-based carrier, the composite coating is pressed onto the electrode substrate at an elevated temperature within the range of about 25-250 degrees C., and more preferably within the range of about 100-250 degrees C., and a minimum pressure of about 1500 psi. Since the lead alloy substrate is in the form of thin lead sheets of about three feet by five feet, the improved electrode tends to bend and warp during heating, and, thus, the composite coated electrode is straightened and then is ready for service.

Three examples of the preparation, testing, and performance of the improved composite coated electrode of the present invention are as follows.

### EXAMPLE 1

A composite mixture having the composition of 10 weight percent binder, 3 weight percent chopped carbon fiber, 21 weight percent lead dioxide and 66 weight percent manganese dioxide was blended and slurried with an alcohol water mixture carrier and applied to a cleaned lead alloy sheet substrate by brushing to form a coating of the composite mixture on the substrate. After drying, the composite coated electrode was pressed at 200 degrees C., 2500 psi pressure, for 10 seconds. After cooling, the composite coated electrode was used as an anode in a cell containing a copper electrolyte from a commercial operation. Electrolysis was accomplished at 34 mA/cm² for 7 days. The cell with the composite coated anode was compared with a cell utilizing the same current density but an uncoated lead alloy anode. The cell voltage was lowered in the composite coated anode cell by 120 mV versus the uncoated lead alloy anode cell.

### EXAMPLE 2

A composite coated electrode prepared similarly to Example 1 with 6 weight percent binder, 2 weight percent carbon fiber and the balance of mixed manganese and lead dioxide after use at 240 Amps per square meter for 276 days (approximately 9 months) was used to perform an electrowinning test for two days and compared with a normal uncoated lead alloy anode of an approximate age of 6 months. The cell voltage was lowered by approximately 40 mV by use of the composite coated anode and the increased current efficiency was 1.5%. Continued testing to a harvest time of one week yielded an improved current efficiency of 4.2%.

### EXAMPLE 3

A set of anodes, made in accordance with the principles of the present invention, were used in a commercial cell for approximately eighty days. At this time the cells were cleaned of sludge and the composite anode containing cell had less than five percent (5%) the amount of sludge in the cell as compared to a normal cell having an anode made by the prior art practice. This is an example of corrosion inhibition of the lead alloy by the composite coating.

Results of the testing of the composite coated anode versus the prior art lead alloy anode under laboratory and commercial conditions are summarized below for copper and zinc production:

1. The corrosion of the lead alloy is inhibited by the composite coating which is the new site of electrochemical oxidation.

2. The potential of the cell with the composite coated electrode is typically but not always lowered 50-150 mV initially but this appears to be somewhat absent with time.

3. A cell with the composite coated electrode will have a higher current efficiency of the cathodic reaction which is typically improved by 2-8% in copper electrowinning. In zinc electrowinning insufficient data was generated to fully assess the improvement in cathode current density.

4. A composite coated electrode will have less manganese dioxide anode flake produced from manganese impurities in the electrolyte in copper electrowinning. Typically there is a low level of manganese of less than 0.25 gram per liter. Manganese (III), (IV), and (VII) are produced in zinc electrolytes where the manganese concentration is 2-10 grams per liter. The composite coating inhibits manganese oxidation to sludge forming materials and there is a lot less manganese oxide sludge in a cell with composite coated anodes.

5. Surface analysis of the composite coated electrode and the uncoated lead alloy electrode has shown that the uncoated lead alloy surface produces a large amount of lead dioxide and some lead sulfate along with manganese bearing materials. The surface of the composite coated electrode is more lead sulfate than lead dioxide and contains manganese materials.

Because of the above results, the use of the composite coated lead alloy electrode reduces the maintenance of the electrode and stabilizes cell performance. It should also be mentioned that the substrate of the improved composite coated electrode can be a lead alloy grid or other grid material adapted use of the electrode in a lead acid battery or other electrochemical power system. Also the metal oxides can be replaced with other electrochemically active agents, such as other metal oxides, nitrides, carbides etc., in order to establish or alter a preferred electrochemical reaction. The composite mixture to form the coating can be applied to the substrate by numerous conventional methods, such as dry powder, slurry paste, slurry spray, sputtering, and electrostatic deposition. The composite coated electrode when used as an anode in copper and zinc electrowinning achieves the attendant results of lowering the oxidation products of manganese (II) and iron (II) species in the electrolyte and therefore of increasing cell product efficiency in metal produced and lowering the amount of sludge products. And composite coated lead alloy anodes are more efficient in zinc and copper cell operations with regards to: (a) current efficiency of the cathode product in copper; (b) less maintenance; and (c) less sludge due to corrosion inhibition of lead.

It is thought that the present invention and its advantages will be understood from the foregoing description and it will be apparent that various changes may be made thereto without departing from the spirit and scope of the invention or sacrificing all of its material advantages, the form hereinbefore described being merely preferred or exemplary embodiment thereof.

I claim:

1. A coated composite electrode for supporting an electrochemical reaction, said electrode comprising:
(a) a substrate composed of an electrically conductive metal; and
(b) a mixture composed of lead and manganese oxides of 5 between about 70 and 90 weight percent and of binders and extenders together being of between about 10 and 30 weight percent, said mixture being in the form of a coating on said substrate which constitutes a site of electrochemical oxidation.

2. The electrode as recited in claim 1, wherein said coating is pressed above about 1500 psi pressure.

3. The electrode as recited in claim 2, wherein said coating when pressed is at a temperature within the range of about 25 to 230 degrees C.

4. The electrode as recited in claim 1, wherein said electrically conductive metal is a lead alloy.

5. The electrode as recited in claim 1, wherein said binders are polyvinylidene difluoride or its copolymers.

6. The electrode as recited in claim 1, wherein said extenders are carbon fibers, absorbants or the like.

7. The electrode as recited in claim 1, wherein said electrode is a positive electrode used in a lead acid battery.

8. The electrode as recited in claim 1, wherein said electrode is an electrode used in an electrochemical power system.

9. A method of fabricating a composite coated electrode, comprising the steps of:
(a) providing a substrate composed of an electrically conductive metal;
(b) providing a mixture composed of lead and manganese oxides of between about 70 and 90 weight percent and of binders and extenders together being of between about 10 and 30 weight percent; and
(c) applying the mixture to the substrate so as to form a coating thereon which constitutes a site of electrochemical oxidation.

10. The method as recited in claim 9, wherein said mixture to form said coating is applied as a dry powder.

11. The method as recited in claim 9, wherein said mixture to form said coating is applied as a slurry paste.

12. The method as recited in claim 9, wherein said mixture to form said coating is applied as a slurry spray.

13. The method as recited in claim 9, wherein said mixture to form said coating is applied by sputtering.

14. The method as recited in claim 9, wherein said mixture to form said coating is applied by electrostatic deposition.

15. The method as recited in claim 9 wherein said mixture to form said coating is pressed above 1500 psi pressure.

16. The method as recited in claim 9, wherein said mixture when pressed is at a temperature within the range of about 25 to 230 degrees C.

17. The method as recited in claim 9, wherein said electrically conductive metal is a lead alloy.

18. The method as recited in claim 9, wherein said binders are polyvinylidene difluoride or its copolymers.

19. The method as recited in claim 9, wherein said extenders are carbon fibers, absorbents or the like.

20. The method as recited in claim 9, wherein said electrode is a positive electrode used in a lead acid battery.

21. The method as recited in claim 9, wherein said electrode is an electrode used in an electrochemical power system.
